(19) United States
(12) Patent Application Publication
(10) Pub. No.: US 2014/0363771 A1
(43) Pub. Date: Dec. 11, 2014

(54) DISPLAY PANEL AND MANUFACTURING METHOD THEREOF AND IMAGE DISPLAY SYSTEM

(71) Applicant: INNOLUX CORPORATION, Miao-Li County (TW)

(72) Inventors: Hung-Ming SHEN, Miao-Li County (TW); Wan-Ling HUANG, Miao-Li County (TW); Kai-Neng YANG, Miao-Li County (TW); Tsau-Hua HSIEH, Miao-Li County (TW)

(21) Appl. No.: 14/466,135

(22) Filed: Aug. 22, 2014

Related U.S. Application Data
(62) Division of application No. 13/712,022, filed on Dec. 12, 2012, now abandoned.

(30) Foreign Application Priority Data
Dec. 15, 2011 (TW) 100146408

(51) Int. Cl. G03F 7/20

(52) U.S. Cl. CPC G03F 7/2002
USPC 430/319

(57) ABSTRACT

An embodiment of the invention provides a manufacturing method of a display panel. The method includes: providing a first substrate, a second substrate and a liquid crystal layer sandwiched therebetween, wherein the liquid crystal layer is doped with a photopolymerization monomer, and the first substrate has a first surface facing the liquid crystal layer, and the second substrate has a second surface facing the liquid crystal layer; and performing an irradiation process on the liquid crystal layer by using a photomask to polymerize the photopolymerization monomer, so as to form a first alignment layer with a first trench pattern on the first surface and a second alignment layer with a second trench pattern on the second surface.

### CROSS REFERENCE TO RELATED APPLICATIONS

This Application is a Divisional of pending U.S. patent application Ser. No. 13/712,022, filed on Dec. 12, 2012, which claims priority of Taiwan Patent Application No. 100146408, filed on Dec. 15, 2011, the entireties of which are incorporated by reference herein.

### BACKGROUND OF THE INVENTION

1. Field of the Invention

The present invention relates to a display device, and in particular, relates to a display panel and manufacturing methods thereof.

2. Description of the Related Art

Liquid-crystal displays have many advantages, such as being comparably light and thin, and having low power consumption, so liquid-crystal displays have become the most popular type of displays used. The liquid-crystal display includes a liquid-crystal display panel and a backlight module. The liquid-crystal display panel includes a thin-film transistor substrate, a color filter substrate, and a liquid-crystal layer sandwiched therebetween. The backlight module is used to provide light. The liquid crystal molecules of the liquid crystal layer may rotate by applying an electric field on the liquid crystal molecules, such that the polarizing direction of the light passing through the liquid crystal layer may be modulated, and thus, the liquid crystal display panel may modulate the light and display images.

Furthermore, each of the thin-film transistor substrate and the color filter substrate has an alignment layer providing the boundary conditions of the arrangement of the liquid crystal molecules, such that the liquid crystal molecules may be arranged in the design direction to achieve uniform display. Also, the alignment layer may provide a pre-tilt angle, such that when the liquid crystal molecules are driven by the electric field, the liquid crystal molecules may rotate in the same direction, which improves the driving speed.

The alignment method commonly used is rubbing alignment. Specifically, for the rubbing alignment method, a flannel roller provides a mechanical rubbing action to the surface of the polyimide layer (i.e. the alignment layer), such that polymer main chains are arranged in a same direction to align the liquid crystal molecules. However, this method (i.e. rubbing alignment) causes many problems, such as non-uniform alignment, particles, remained static electricity and scratches, thus, decreasing process yields. Furthermore, the method requires purchase of polyimide coating machines and polyimide solutions to perform the alignment film coating process, which significantly increases manufacturing costs.

### BRIEF SUMMARY OF THE INVENTION

An embodiment of the invention provides a display panel which includes: a first substrate; a second substrate disposed on the first substrate; a liquid crystal layer sandwiched between the first substrate and the second substrate; a first alignment layer disposed on a first surface of the first substrate facing the liquid crystal layer, and having a first trench pattern; and a second alignment layer disposed on a second surface of the second substrate facing the liquid crystal layer, and having a second trench pattern, wherein the first alignment layer and the second alignment layer are formed by polymerizing a photopolymerization monomer

An embodiment of the invention provides a manufacturing method of a display panel, which includes: providing a first substrate, a second substrate and a liquid crystal layer sandwiched therebetween, wherein the liquid crystal layer is doped with a photopolymerization monomer, and the first substrate has a first surface facing the liquid crystal layer, and the second substrate has a second surface facing the liquid crystal layer; and performing an irradiation process on the liquid crystal layer by using a photomask to polymerize the photopolymerization monomer, so as to form a first alignment layer with a first trench pattern on the first surface and a second alignment layer with a second trench pattern on the second surface

An embodiment of the invention provides an image display system, which includes: a display panel as described above; and an input unit electrically connected to the display panel to provide input signals to the display panel, such that the display panel displays images.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIGS. 1A-1C are cross-sectional views illustrating a display panel manufacturing process according to an embodiment of the present invention;

FIG. 2 is a perspective view of the photomask according to an embodiment of the present invention;

FIG. 3 is a cross-sectional view illustrating a display panel manufacturing process according to another embodiment of the present invention; and

FIG. 4 shows an image display system according to an embodiment of the present invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

It is understood, that the following disclosure provides many different embodiments, or examples, for implementing different features of the invention. Specific examples of components and arrangements are described below to simplify the present disclosure. These are, of course, merely examples and are not intended to be limiting. In addition, the present disclosure may repeat reference numbers and/or letters in the various examples. This repetition is for the purpose of simplicity and clarity and does not in itself dictate a relationship between the various embodiments and/or configurations discussed. Furthermore, descriptions of a first layer “on,” “overlying,” (and like descriptions) a second layer, include embodiments where the first and second layers are in direct contact and those where one or more layers are interposing the first and second layers.

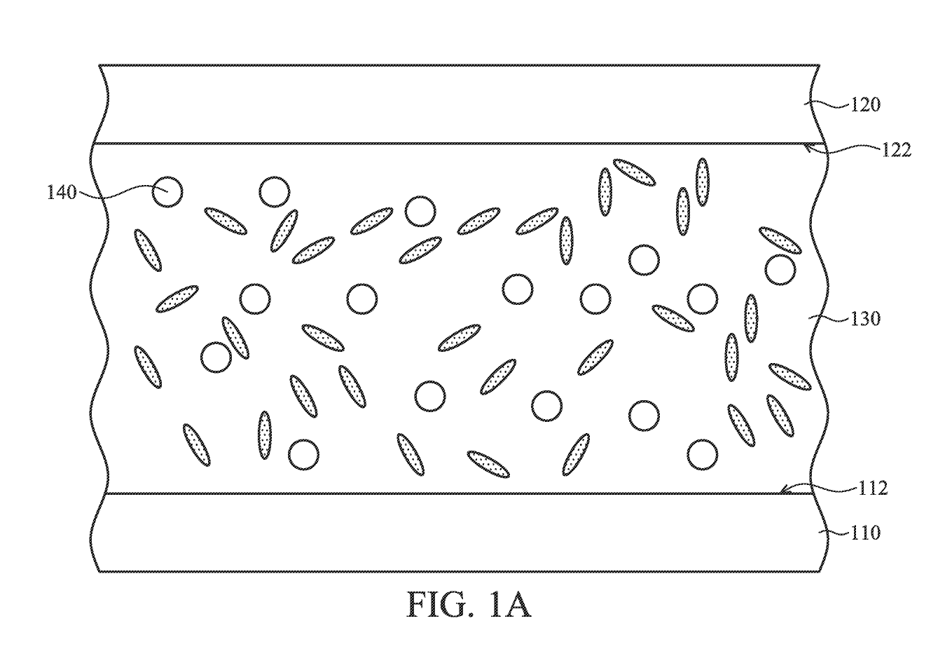

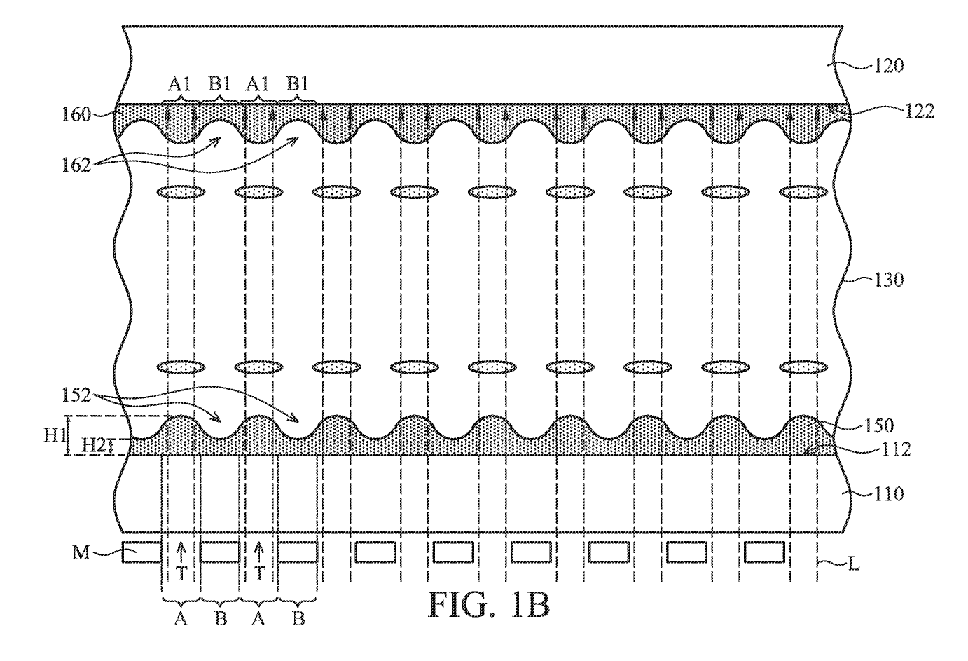

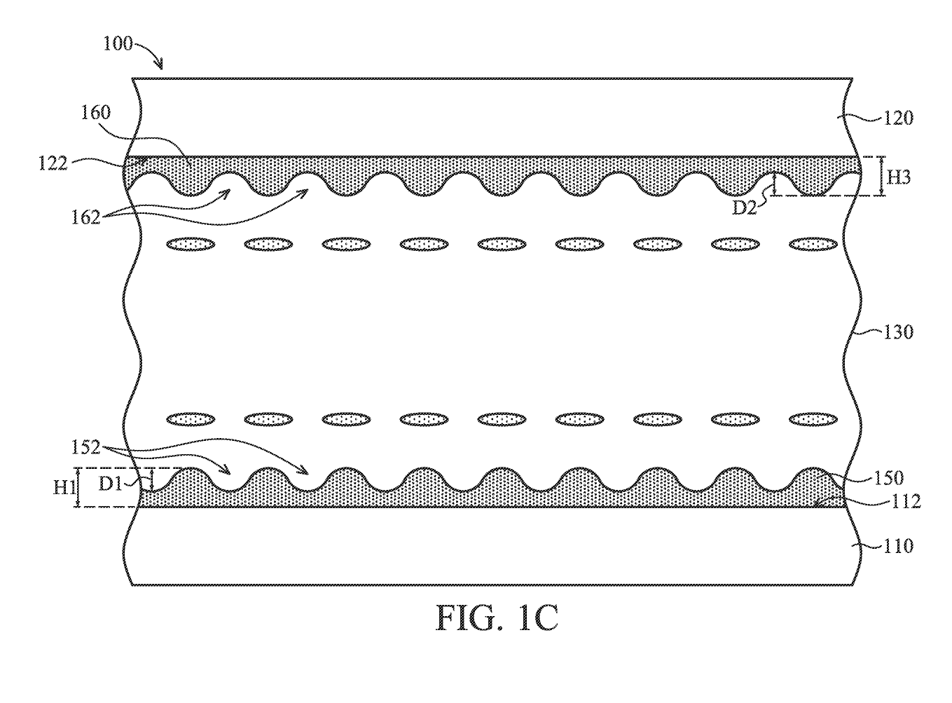

FIGS. 1A-1C are cross-sectional views illustrating a display panel manufacturing process according to an embodiment of the present invention. Firstly, referring to FIG. 1A, a first substrate 110, a second substrate 120 and a liquid crystal layer 130 sandwiched therebetween are provided. The first substrate 110 has a first surface 112 facing the liquid crystal layer 130, and the second substrate 120 has a second surface 122 facing the liquid crystal layer 130.

The liquid crystal layer 130 is doped with a photopolymerization monomer 140, such as an acrylic monomer. In one embodiment, the doped ratio of the photopolymerization monomer 140 may range from 0.1 wt % to 3.5 wt %. In one embodiment, the photopolymerization monomer 140 may be selected from a group consisting of diacrylate series (i.e. the monomer having a diacrylate group), triacrylate series (i.e. the monomer having a triacrylate group), phenylpropionic acid, Coumarin, acrylic monomers and combinations thereof

The diacrylate series includes:

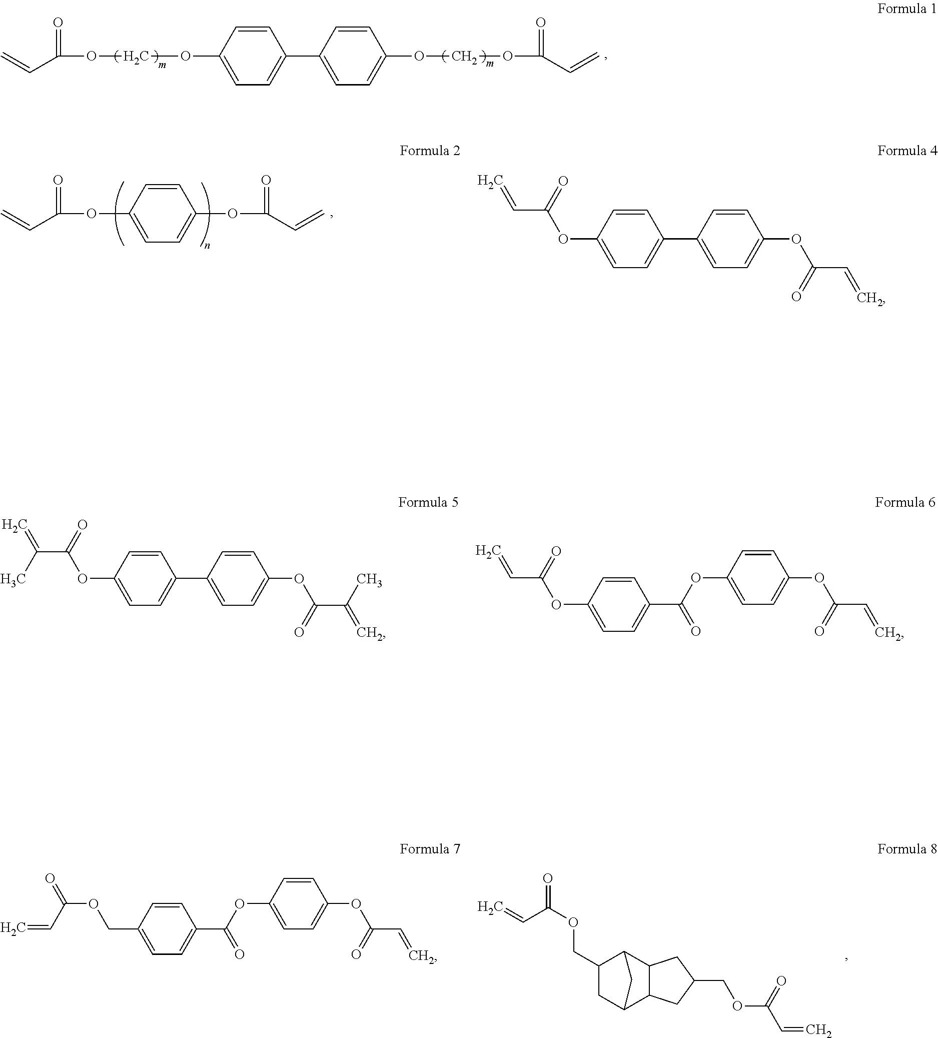

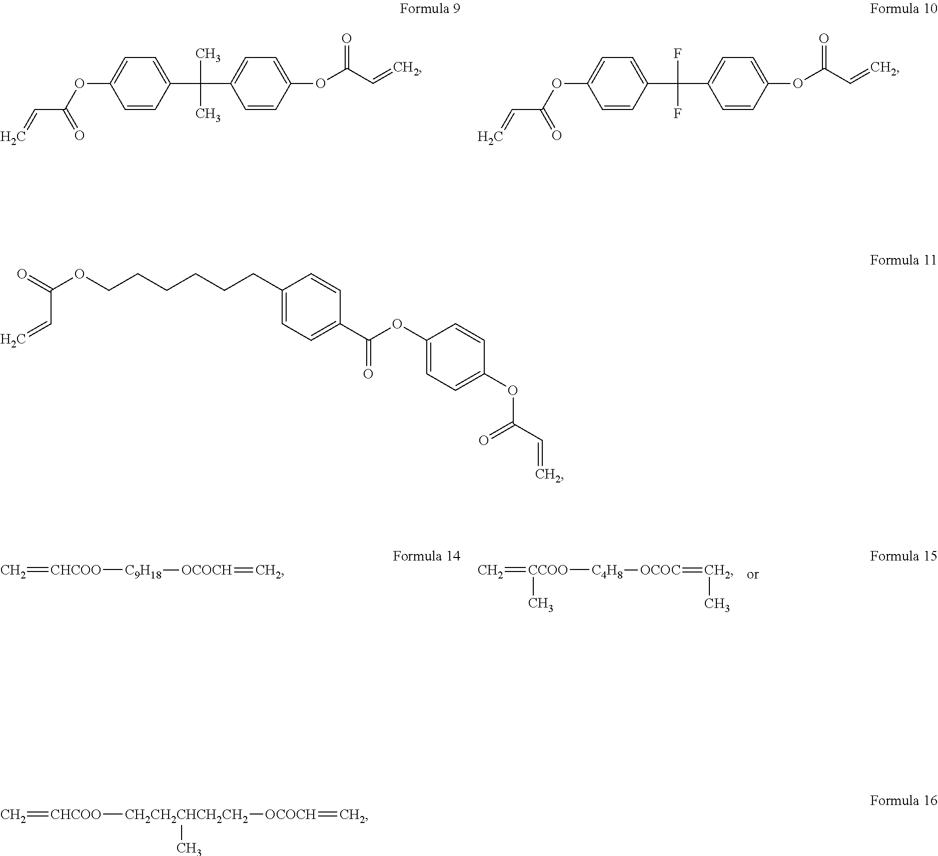

wherein 5>m>1 in Formula 1, and 5>n>1 in Formula 2. “m” and “n” are integrals. The triacrylate series includes:

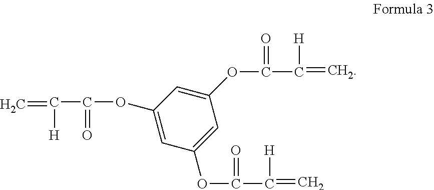 [SMILES: C=CC(=O)Oc1cc(OC(=O)C=C)cc(OC(=O)C=C)c1]

The phenylpropionic acid includes:

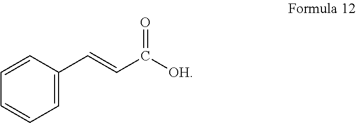 [SMILES: O=C(O)/C=C/c1ccccc1]

The Coumarin includes:

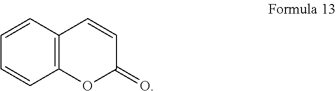 [SMILES: O=c1ccc2ccccc2o1]

Next, referring to FIG. 1B, an irradiation process is performed on the liquid crystal layer 130 by using a photomask M to polymerize the photopolymerization monomer 140 (as shown in FIG. 1A), so as to form a first alignment layer 150 with a first trench pattern 152 on the first surface 112 and a second alignment layer 160 with a second trench pattern 162 on the second surface 122.

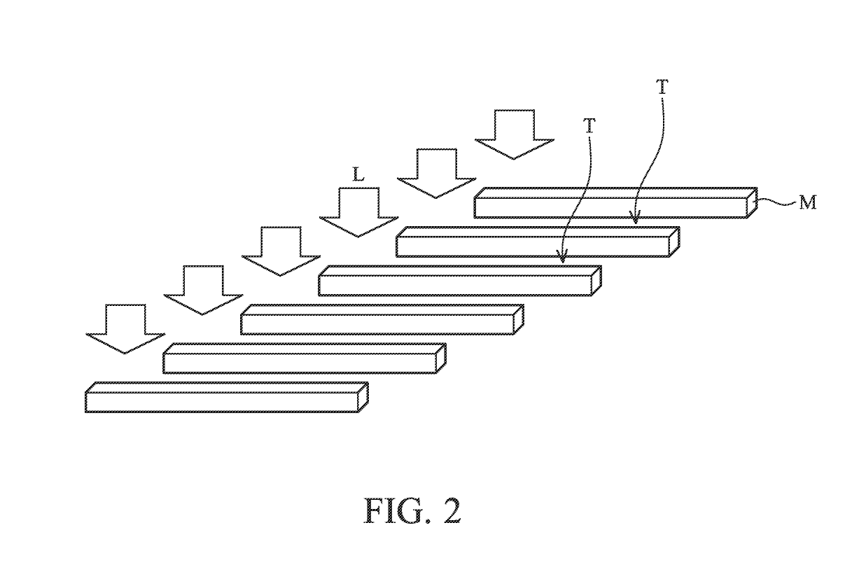

FIG. 2 is a perspective view of the photomask according to an embodiment of the present invention. Specifically, referring to FIGS. 1B and 2, in one embodiment, the photomask M may have a plurality of slots T, and the light beam L may pass through the slots T to irradiate the photopolymerization monomer 140 doped in the liquid crystal layer 130 to polymerize the photopolymerization monomer 140, thereby forming a polymer. In this case, because the liquid crystal layer 130 cannot encapsulate the polymer, the polymer may aggregate to the outside of the liquid crystal layer 130 (i.e. the first surface 112 of the first substrate 110 and the second surface 122 of the second substrate 120) so as to form a first alignment layer 150 on the first surface 112 and a second alignment layer 160 on the second surface 122.

Furthermore, because the photopolymerization reaction is carried out by irradiating the photopolymerization monomer 140 to form the alignment layer, the alignment layer is formed in the region A of the first surface 112 corresponding to the slots T (and the region Al of the second surface 122 corresponding to the slots T) during the irradiation process. If the slots T have a smaller width, a diffraction phenomenon occurs when the light beam L passes through the slots T. If the spacing between the slots T is smaller, the irradiation process may also form the alignment layer in the region B of the first surface 112 corresponding to the material portion of the photomask M (and the region B1 of the second surface 122 corresponding to the material portion of the photomask M). The portion of the alignment layer corresponding to the material portion of the photomask M has a thickness H2 (i.e. the minimum thickness), which is less than a thickness H1 of the portion of the alignment layer corresponding to the slots T (i.e. the maximum thickness). Thus, the first alignment layer 150 has a first trench pattern 152 corresponding to the material portion of the photomask M. The second alignment layer 160 has a second trench pattern 162 corresponding to the material portion of the photomask M. The material portion of the photomask M is an opaque portion of the photomask M, and the slots T are a transparent portion of the photomask M.

It should be noted that, in the present embodiment, the first alignment layer 150 and the second alignment layer 160 are formed by irradiating the photopolymerization monomer 140 doped in the liquid crystal layer 130, thus, polymerization occurs to form a polymer, wherein the polymer aggregates on the outside of the liquid crystal layer 130. Thus, no polyimide coating machine used in the related art is required in the present embodiment, which significantly decreases the manufacturing costs.

The present embodiment uses the photopolymerization reaction characteristics of the photopolymerization monomer 140 and the photomask M to perform the irradiation process, so the first alignment layer 150 and the second alignment layer 160 have the first trench pattern 152 and the second trench pattern 162, respectively. Therefore, the present embodiment directly forms the alignment layers with the trench patterns, so the present embodiment does not need to adopt the conventional rubbing alignment method, thus, avoiding the conventional problems caused by mechanically rubbing the alignment layer (such as non-uniform alignment, particles and remained static electricity), thus, process yields may be significantly improved.

In one embodiment, the irradiation process is performed by irradiating the photopolymerization monomer 140 with the light beam from a surface of the first substrate 110 opposite to the first surface 112. The first substrate 110 and the second substrate 120 are, for example, an active array substrate and a color filter substrate, respectively. In one embodiment, the irradiation process adopts ultraviolet light, such as linear polarization ultraviolet light. The ultraviolet light energy of the irradiation process ranges, for example, from 10 mW to 80 mW. The irradiation time ranges, for example, from 60 sec to 1200 sec. The total irradiation energy density ranges, for example, from 0.6 J/cm²-9.6 J/cm². The wavelength of the ultraviolet light ranges, for example, from 20 nm to 400 nm.

Next, referring to FIG. 1C, the photomask M is removed, and a display panel 100 is formed.

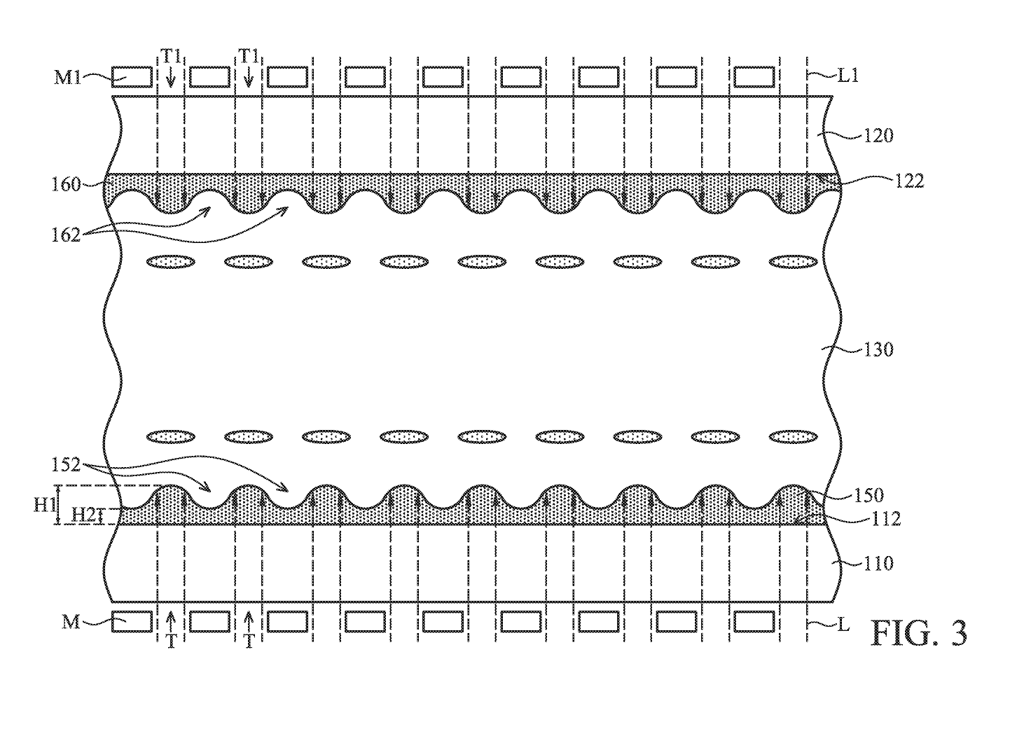

FIG. 3 is a cross-sectional view illustrating a display panel manufacturing process according to another embodiment of the present invention. As shown in FIG. 3, in another embodiment, the irradiation process is performed by irradiating the photopolymerization monomer 140 (as shown in FIG. 1A) with the light beam from the surface of the first substrate 110 opposite to the first surface 112 and a surface the second substrate 120 opposite to a the second surface 122. Specifically, a photomask M1 is disposed on the second substrate 120, wherein the photomask M1 may have a plurality of slots T1, and the light beam L1 may pass through the slots T1 to irradiate the photopolymerization monomer 140 doped in the liquid crystal layer 130. The photopolymerization monomer 140 may be irradiated with the light beams L and L1 from the surface of the first substrate 110 opposite to the first surface 112 and the surface of the second substrate 120 opposite to the second surface 122 by using the photomasks M and M1 during the same time (or independently).

The structure of the display panel 100 in FIG. 1C is described in detail as follows.

Referring to FIG. 1C, the display panel 100 of the present embodiment includes a first substrate 110, a second substrate 120, a liquid crystal layer 130, a first alignment layer 150 and a second alignment layer 160, wherein the second substrate 120 is disposed on the first substrate 110, and the liquid crystal layer 130 is sandwiched between the first substrate 110 and the second substrate 120.

The first alignment layer 150 is disposed on a first surface 112 of the first substrate 110 facing the liquid crystal layer 130 and has a first trench pattern 152. The second alignment layer 160 is disposed on a second surface 122 of the second substrate 120 facing the liquid crystal layer 130 and has a second trench pattern 162. The first alignment layer 150 and the second alignment layer 160 are formed from polymerization of a photopolymerization monomer 140 (as shown in FIG. 1A).

It should be noted that the first alignment layer 150 is directly disposed on the first substrate 110, and the second alignment layer 160 is directly disposed on the second substrate 120. There is no other film (such as a polyimide film) sandwiched between the first alignment layer 150 and the first substrate 110, or between the second alignment layer 160 and the second substrate 120.

The thickness H1 of the first alignment layer 150 or the thickness H3 of the second alignment layer 160 (i.e. the maximum thickness) is, for example, 20 Å-80 Å. The depth D1 of the first trench pattern 152 or the depth D2 of the second trench pattern 162 is about 20 Å-40 Å.In one embodiment, the first trench pattern 152 does not pass through the first alignment layer 150, and the second trench pattern 162 does not pass through the second alignment layer 160.

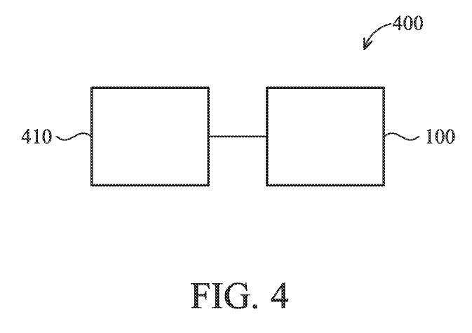

FIG. 4 shows an image display system according to an embodiment of the present invention. As shown in FIG. 4, the image display system 400 of the present embodiment includes a display panel 100 and an input unit 410, wherein the input unit 410 is electrically connected to the display panel 100 to provide input signals to the display panel 100, such that the display panel 100 may display images.

The image display system 400 is, for example, a tablet computer, a projector, an electronic book, a note book, a cell phone, a digital camera, a personal digital assistant, a desktop computer, a television, an automotive display, a portable DVD player or other image display systems.

As described above, in the present invention, the alignment layers are formed by irradiation of the photopolymerization monomer doped in the liquid crystal layer, thus, polymerization occurs to form a polymer, wherein the polymer aggregates on the outside of the liquid crystal layer. Thus, no polyimide coating machine used in the related art is required in the present embodiment, which significantly decreases the manufacturing costs.

Furthermore, the present invention uses the photopolymerization reaction characteristics of the photopolymerization monomer and the photomask to perform the irradiation process, so the present embodiment directly forms the alignment layers with the trench patterns. Thus, the present embodiment does not need to adopt the conventional rubbing alignment method, thus, avoiding the conventional problems caused by mechanically rubbing the alignment layer, thus, process yields may be significantly improved.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A manufacturing method of a display panel, comprising:
providing a first substrate, a second substrate and a liquid crystal layer sandwiched therebetween, wherein the liquid crystal layer is doped with a photopolymerization monomer, and the first substrate has a first surface facing the liquid crystal layer, and the second substrate has a second surface facing the liquid crystal layer; and
performing an irradiation process on the liquid crystal layer by using a photomask to polymerize the photopolymerization monomer, so as to form a first alignment layer with a first trench pattern on the first surface and a second alignment layer with a second trench pattern on the second surface.

2. The manufacturing method of the display panel as claimed in claim 1, wherein the irradiation process is performed by irradiating the photopolymerization monomer from a surface of the first substrate opposite to the first surface.

3. The manufacturing method of the display panel as claimed in claim 1, wherein the irradiation process is performed by irradiating the photopolymerization monomer from a surface of the first substrate opposite to the first surface and a surface of the second substrate opposite to the second surface.

4. The manufacturing method of the display panel as claimed in claim 1, wherein the irradiation process adopts linear polarization ultraviolet light.
